(19) United States
(12) Patent Application Publication
(10) Pub. No.: US 2016/0300996 A1
(43) Pub. Date: Oct. 13, 2016

(54) BULK ACOUSTIC WAVE RESONATOR AND FILTER INCLUDING THE SAME

(71) Applicant: SAMSUNG ELECTRO-MECHANICS CO., LTD., Suwon-si (KR)

(72) Inventors: Tae Kyung LEE, Suwon-si (KR); Sung HAN, Suwon-si (KR); Ran Hee SHIN, Suwon-si (KR); Hwa Sun LEE, Suwon-si (KR); Seung Joo SHIN, Suwon-si (KR)

(73) Assignee: SAMSUNG ELECTRO-MECHANICS CO., LTD., Suwon-si (KR)

(21) Appl. No.: 15/003,045

(22) Filed: Jan. 21, 2016

(30) Foreign Application Priority Data
Apr. 10, 2015 (KR) 10-2015-0051128
Jun. 16, 2015 (KR) 10-2015-0085236

(51) Int. Cl. H03H 9/54; H03H 9/17; H01L 41/047; H03H 9/13

(52) U.S. Cl. CPC H01L 41/0477; H03H 9/13; H03H 9/173; H03H 9/54

(57) ABSTRACT

In examples, there is provided a bulk acoustic wave resonator including: a substrate, a first electrode and a second electrode formed on the substrate, and a piezoelectric layer formed between the first electrode and the second electrode, wherein at least one of the first electrode and the second electrode is formed of an alloy including a molybdenum element. Additionally, such a bulk acoustic wave resonator may include an air cavity formed between the substrate and the first electrode.

### CROSS-REFERENCE TO RELATED APPLICATION(S)

This application claims the benefit under 35 USC 119(a) of Korean Patent Application Nos. 10-2015-0051128 filed on Apr. 10, 2015 and 10-2015-0085236 filed on Jun. 16, 2015 in the Korean Intellectual Property Office, the entire disclosures of which are incorporated herein by reference for all purposes.

### BACKGROUND

1. Field

The following description relates to a bulk acoustic wave resonator. The following description also relates to a filter including the same.

2. Description of Related Art

In accordance with the recent rapid development of mobile communications devices, the demand for compact and lightweight filters, oscillators, resonant elements, acoustic resonant mass sensors, and other similar electronic components used to facilitate mobile communications has increased.

As a means for implementing such compact and lightweight filters, oscillators, resonant elements, acoustic resonant mass sensors, and other similar components, a film bulk acoustic resonator (FBAR) has commonly been used. Such an FBAR has an advantage in that it may be mass-produced at minimal cost and may be subminiaturized. Furthermore, such an FBAR has advantages in that it may allow a high value quality factor Q, which is a main property of an effective filter, to be implemented. Such an FBAR may also operate at levels equal to those of the bands of a personal communications system (PCS) and a digital cordless system (DCS).

Generally, the FBAR has a structure that includes a resonating part formed by sequentially laminating a first electrode, a piezoelectric layer, and a second electrode on a substrate.

An operational principle of such an FBAR is described below. First, when an electric field is induced in the piezoelectric layer by applying electrical energy to the first and second electrodes, the electric field causes a piezoelectric phenomenon in the piezoelectric layer. Such a piezoelectric phenomenon causes the resonating part to vibrate in a predetermined direction. As a result, bulk acoustic waves are generated in the same direction as the vibration direction of the resonating part, thereby causing a resonance phenomenon to occur.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

An aspect of the present examples provides a bulk acoustic wave resonator capable of securing reliability by preventing oxidation of electrodes.

At least one of a plurality of electrodes of a bulk acoustic wave resonator according to an example in formed of an alloy including a molybdenum element.

In one general aspect, a bulk acoustic wave resonator includes a substrate, a first electrode and a second electrode formed on the substrate, and a piezoelectric layer formed between the first electrode and the second electrode, wherein at least one of the first electrode and the second electrode is formed of an alloy comprising molybdenum (Mo).

The alloy may be a molybdenum (Mo)-tantalum (Ta) alloy manufactured by adding tantalum (Ta) to molybdenum (Mo).

A content of tantalum (Ta) in the alloy may be 0.1 to 50 atm %.

A content of tantalum (Ta) in the alloy may be 0.1 to 30 atm %.

The bulk acoustic wave resonator may further include an air cavity formed between the substrate and the first electrode, wherein a sacrificial air cavity layer pattern for forming the air cavity is etched using xenon fluoride.

The sacrificial air cavity layer pattern may be etched after at least one of the first electrode and the second electrode is formed.

In another general aspect, a filter includes bulk acoustic wave resonators, wherein each of the bulk acoustic wave resonators includes a substrate, a first electrode and a second electrode formed on the substrate, and a piezoelectric layer formed between the first electrode and the second electrode, wherein at least one of the first electrode and the second electrode is formed of an alloy including molybdenum.

The alloy may be a molybdenum (Mo)-tantalum (Ta) alloy manufactured by adding tantalum (Ta) to molybdenum (Mo).

A content of tantalum (Ta) in the alloy may be 0.1 to 50 atm %.

A content of tantalum (Ta) in the alloy may be 0.1 to 30 atm %.

Each of the bulk acoustic wave resonators may further include an air cavity formed between the substrate and the first electrode, wherein a sacrificial air cavity layer pattern for forming the air cavity is etched using xenon fluoride.

The sacrificial air cavity layer pattern may be etched after at least one of the first electrode and the second electrode is formed.

The bulk acoustic wave resonators may be formed in a ladder type or a lattice type.

In another general aspect, a bulk acoustic wave resonator includes a first electrode and a second electrode formed on a substrate, a piezoelectric layer formed between the first electrode and the second electrode, and an air cavity formed between the substrate and the first electrode.

A sacrificial air cavity layer pattern for forming the air cavity may be etched using xenon fluoride.

At least one of the first electrode and the second electrode may be formed of an alloy including molybdenum.

The alloy may be a molybdenum (Mo)-tantalum (Ta) alloy manufactured by adding tantalum (Ta) to molybdenum (Mo).

Other features and aspects will be apparent from the following detailed description, the drawings, and the claims.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view of a bulk acoustic wave resonator according to an example.

FIG. 2 is Pourbaix diagrams according to electrode materials.

FIG. 3 illustrates a phase diagram for each type of molybdenum (Mo) alloy.

FIG. 4 illustrates a Raman shift for each type of molybdenum (Mo) alloy.

FIG. 5 illustrates a change in sheet resistance of a molybdenum (Mo) alloy according to an example.

FIGS. 6A and 6B are diagrams illustrating crystal orientation of a piezoelectric layer at a molybdenum (Mo) alloy phase according to an example.

FIGS. 7 and 8 are schematic circuit diagrams of a filter according to examples.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Hereinafter, examples are described in further detail with reference to the accompanying drawings.

The term “atm %” is used to indicate the proportion of an element in a metallic alloy, such that if a certain metal is said to have a content of “x atm %”, where x stands for a number, x percent of the atoms in the alloy are atoms of the given metal.

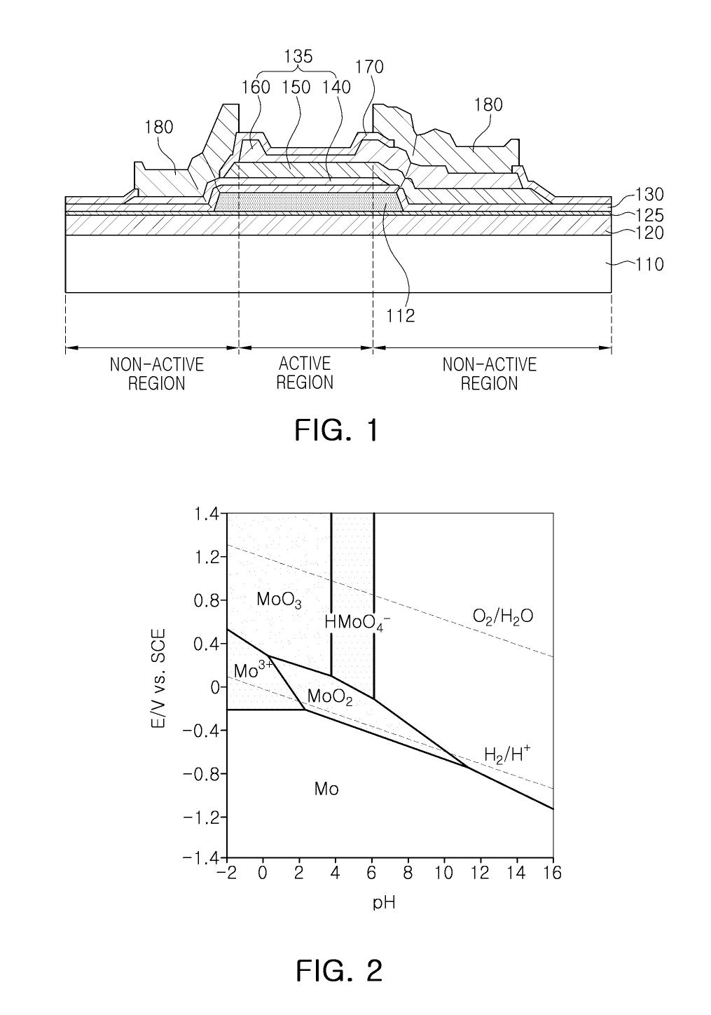

FIG. 1 is a cross-sectional view illustrating a bulk acoustic wave resonator according to an example.

Referring to the example of FIG. 1, a bulk acoustic wave resonator 100 according to an example is a film bulk acoustic resonator (FBAR) and includes a substrate 110, an insulating layer 120, an air cavity 112, and a resonating part 135.

In the example of FIG. 1, the substrate 110 is formed of a typical silicon substrate, and the insulating layer 120 that electrically insulates the resonating part 135 from the substrate 110 is formed on an upper surface of the substrate 110. For example, the insulating layer 120 is formed by depositing silicon dioxide (SiO₂) or aluminum oxide (Al₂O₂) on the substrate 110 by a chemical vapor deposition method, an RF magnetron sputtering method, or an evaporation method. However, these are merely examples other appropriate deposition methods are used in other examples to deposit the insulating layer.

In such an example, the air cavity 112 is disposed above the insulating layer 120. Thus, the air cavity 112 is disposed below the resonating part 135 so that the resonating part 135 is vibrated in a predetermined direction. In an example, the air cavity 112 is formed by processes of first forming a sacrificial air cavity layer pattern on the insulating layer 123. Such a process is followed by forming a membrane 130 on the sacrificial air cavity layer pattern, and then etching and removing the sacrificial air cavity layer pattern.

In such an example, an etch-stop layer 125 is further formed between the insulating layer 120 and the air cavity 112. In this example, the etch-stop layer 125 serves to protect the substrate 110 and the insulating layer 120 from an etching process and serves as a base, as required, to deposit various other layers on the etch-stop layer 125.

Thus, the air cavity 112 is formed by processes of forming a sacrificial air cavity layer pattern on the insulating layer 120, then forming a membrane 130 on the sacrificial air cavity layer pattern, and etching and removing the sacrificial air cavity layer pattern. For example, the membrane 130 serves as an oxidation protection layer or serves as a protection layer for protecting the substrate 110.

In this example, the resonating part 135 includes a first electrode 140, a piezoelectric layer 150, and a second electrode 160 that are sequentially laminated so as to be disposed above the air cavity 112.

The first electrode 140 is formed on an upper surface of the membrane 130 so as to cover a portion of the membrane 130. The piezoelectric layer 150 is formed on an upper surface of the membrane 130 and the first electrode 140 so as to cover a portion of the membrane 130 and a portion of the first electrode 140. The piezoelectric layer 150 is a part in which a piezoelectric effect is generated by converting electrical energy into mechanical energy of an acoustic wave type. For example, the piezoelectric layer 150 is formed of aluminum nitride (AlN), zinc oxide (ZnO), lead zirconium titanium oxide (PZT; PbZrTiO), or another similar material with appropriate piezoelectric properties. Accordingly, the second electrode 160 is formed on the piezoelectric layer 150.

Furthermore, in such an example, the resonating part 135 is classified as having an active region and non-active regions. The active region of the resonating part 135 is a region that is vibrated in a predetermined direction by a piezoelectric phenomenon to create resonance when electrical energy is applied to the first and second electrodes 140 and 160 to induce an electric field in the piezoelectric layer 150. For example, the active region corresponds to a region in which the first electrode 140, the piezoelectric layer 150, and the second electrode 160 overlap with each other in a vertical direction above the air cavity 112. The non-active regions of the resonating part 135 are regions that are not resonated by the piezoelectric phenomenon, even in the case that electrical energy is applied to the first and second electrodes 140 and 160. For example, the non-active regions correspond to outer regions of the active region.

The resonating part 135 having the configuration as described above filter an RF signal of a specific frequency using the piezoelectric effect of the piezoelectric layer 150, as described further above.

Accordingly, the resonating part 135 resonates the piezoelectric layer 150, depending on the RF signals applied to the first electrode 140 and the second electrode 160, to generate an acoustic wave having a specific resonance frequency and an anti-resonance frequency. Thus, the resonance penomenon in the piezoelectric layer 150 occurs when a half of a wavelength of the applied RF signal corresponds to a thickness of the piezoelectric layer 150. Since electrical impedance sharply varies when the resonance phenomenon occurs, the bulk acoustic wave resonator according to an example is used as a filter that capable of selecting a frequency. More specifically, the resonating part 135 has a constant resonance frequency according to the vibration occurring in the piezoelectric layer 150. Accordingly, the resonating part 135 outputs only a signal matched to the resonance frequency of the resonating part 135, among the applied RF signals.

For example, a protection layer 170 is disposed on the second electrode 160 of the resonating part 135 in order to prevent the second electrode 160 from being exposed externally and oxidized. Additionally, an electrode pad 180 for applying an electrical signal is formed on the first electrode 140 and the second electrode 160, which are exposed externally.

FIG. 2 is Pourbaix diagrams according to electrode materials. A Pourbaix diagram maps out possible stable equilibrium phases of an aqueous electrochemical system.

Typically, the first and second electrodes 140 and 160 are formed of a material such as gold (Au), titanium (Ti), tantalum (Ta), molybdenum (Mo), ruthenium (Ru), platinum (Pt), tungsten (W), aluminum (Al), or nickel (Ni). However, these are only examples and other appropriate materials are used in other examples. Particularly, in order to increase desirable crystal orientation of the piezoelectric layer 150, molybdenum (Mo) may be used is the material for the first and second electrodes 140 and 160.

However, referring to the example of FIG. 2, molybdenum (Mo) material potential problems in that it tends to dissolve at a pH of 4 to 7 and tends to be oxidized in other pH regions. In order to address the above-mentioned issues, molybdenum (Mo) is hermetically sealed to be passivation-treated. Here, being passivation-treated refers to using a sealant to protect the molybdenum from external environmental factors.

However, even in the case in which molybdenum (Mo) is passivation-treated as described above, when molybdenum (Mo) is exposed to moisture at the time of a moisture treatment process, it is to be understood that molybdenum (Mo) is oxidized. Since oxidized molybdenum (Mo) also has high solubility, such oxidization causes a reliability problem. Particularly, in order to connect the first electrode 140 to an external circuit, when a specific region of the first electrode 140 is opened by a trench and is then connected to the electrode pad 180 of FIG. 1, connection and contact defects are caused.

In order to address the above-mentioned problems, in an example in which the electrodes 140 and 160 are formed of metals other than molybdenum (Mo), problems that high specific resistance is involved and orientation is decreased at the time of depositing the piezoelectric layer 150 potentially occur.

Thus, the electrodes according to an example are formed of molybdenum (Mo) alloy.

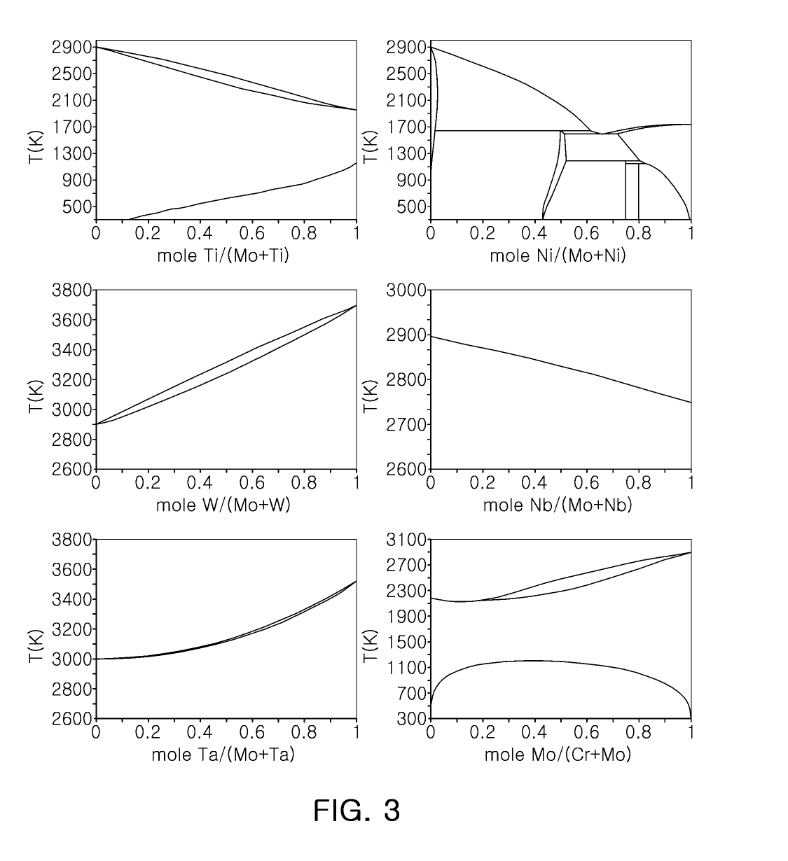

FIG. 3 illustrates a phase diagram for each type of molybdenum (Mo) alloy.

Referring to FIG. 3, a molybdenum (Mo)-tantalum (Ta) alloy, a molybdenum (Mo)-tungsten (W) alloy, and a molybdenum (Mo)-niobium (Nb) alloy, correspond to homogeneous solid solutions formed in a single phase when a temperature is decreased in a liquid phase. For example, such alloys have the same atomic structure such as a body-centered cubic (BCC) structure. Thus, orientation characteristics of a piezoelectric thin film deposited in the molybdenum (Mo) phase are improved.

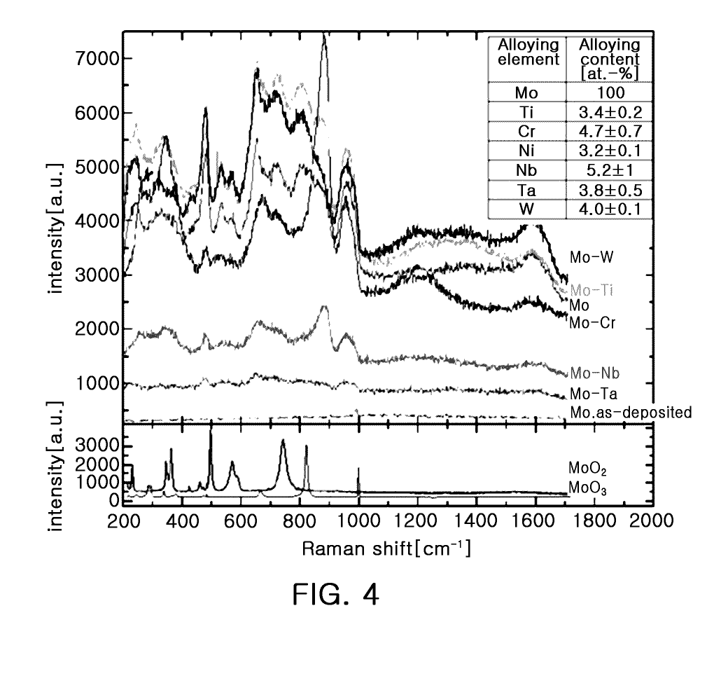

FIG. 4 illustrates a Raman shift for each type of molybdenum (Mo) alloy. Specifically, FIG. 4 illustrates a result of a Raman shift after an 8585 reliability test, wherein an 8585 test is a test under a temperature of 85° C. and humidity of 85%, is performed for a sample of the molybdenum (Mo) alloy.

It may be seen that MoO₂, MoO₃, and the like were not detected immediately after pure molybdenum (Mo) was deposited, but a great quantity of MoO₂ and MoO₃ was detected after the 8585 reliability test was performed.

In addition, it is observable that even in the example of a molybdenum (Mo)-tungsten (W) alloy, a molybdenum (Mo)-titanium (Ti) alloy, a molybdenum (Mo)-nickel (Ni) alloy, and a molybdenum (Mo)-chromium (Cr) alloy, molybdenum (Mo) was oxidized. However, it is observable that in the example of a molybdenum (Mo)-niobium (Nb) alloy, an oxide was less formed than the kinds of alloy described above, but was more formed than in the example of a molybdenum (Mo)-tantalum (Ta) alloy.

It is observable that in an example of a molybdenum (Mo)-tantalum (Ta) alloy manufactured by adding a tantalum (Ta) element to a molybdenum (Mo) element, the oxide formation is significantly reduced.

Thus, according to an example, at least one of the first and second electrodes 140 and 160 is formed of the molybdenum (Mo)-tantalum (Ta) alloy. As a result, the oxidation problem that is potentially caused when pure molybdenum (Mo) is used is solved, accordingly increasing environmental reliability.

In such an example, using the molybdenum (Mo)-tantalum (Ta) alloy, a content of tantalum (Ta) is 0.1 to 50 atm %. In such an example in which the content of tantalum (Ta) is 0.1 to 50 atm %, low specific resistance characteristics are provided in molybdenum (Mo).

Furthermore, in the molybdenum (Mo)-tantalum (Ta) alloy, the content of tantalum (Ta) is potentially 0.1 to 30 atm %. In such an example, in which the content of tantalum (Ta) is 0.1 to 30 atm %, an etching process is easily performed. Also, high orientation for the piezoelectric effect is achieved when the piezoelectric layer 150 is located on the molybdenum (Mo)-tantalum (Ta) alloy.

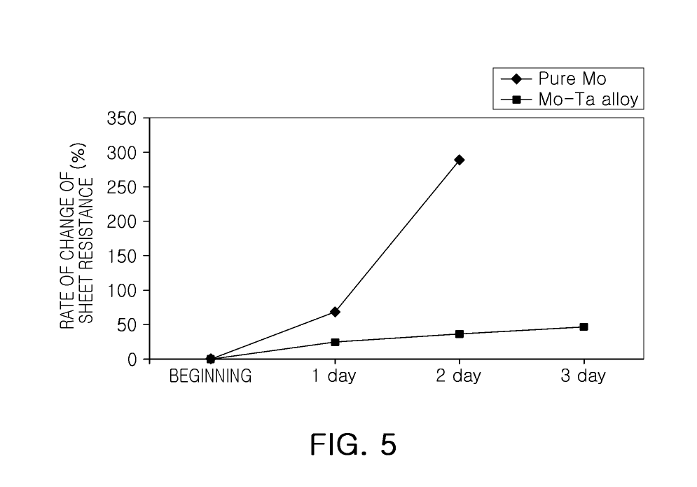

FIG. 5 illustrates a change in sheet resistance of a molybdenum (Mo) alloy according to an example. Specifically, FIG. 5 illustrates a result of a change in sheet resistance after an 8585 reliability test, where such a test is a test under a temperature of 85° C. and humidity of 85%, was performed on a sample of the molybdenum (Mo) alloy.

It is observable that sheet resistance of pure molybdenum (Mo) was sharply increased after two days after the deposition and was outside of a measurement range. However, the molybdenum (Mo)-tantalum (Ta) alloy had a rate of change (%) of sheet resistance that was less than 50%, even after three days. Also, a sheet resistance of the alloy was not significantly changed even in a high temperature and high humidity environment.

The following Table 1 is provided to illustrate etching characteristics of a molybdenum (Mo) alloy, according to an example.

As described above, the air cavity 112 is formed by etching the sacrificial air cavity layer pattern. An etching process of the sacrificial air cavity layer tern is performed using xenon fluoride (XeF₂). In such an example, the etching process is performed after the electrodes are formed. In an example in which the electrodes are unnecessarily etched or corroded by the etching process, a problem in which reliable resonance characteristics of the bulk acoustic wave resonator are not secured possibly occurs.

According to an example, the electrodes are formed of the molybdenum (Mo)-tantalum (Ta) alloy to secure robust characteristics for the etching material, as discussed above.

Table 1 is a table illustrating etching characteristics of pure molybdenum (Mo) and a molybdenum (Mo)-tantalum (Ta) alloy for xenon fluoride (XeF₂). In order to perform a test of Table 1, after pure molybdenum (Mo) and a molybdenum (Mo)-tantalum (Ta) alloy were deposited, a portion of a deposition layer was removed in the shape of a circular region having a diameter of 30 μm, and an inner portion of the circular region was etched with xenon fluoride (XeF₂).

TABLE 1

| | Thickness of | Diameter of | Amount of |
|---|---|---|---|
| | Deposition | Circle | Etching |
| Molybdenum (Mo) | 224 nm | 68.99 μm | 38.99 μm |
| Molybdenum (Mo)-Tantalum | 136 nm | 51.13 μm | 21.13 μm |
| (Ta) Alloy | | | |

As seen from Table 1, a size of pure molybdenum (Mo) was increased from 30 μm to 68.99 μm, such that 38.99 μm is etched, while a size of a molybdenum (Mo)-tantalum (Ta) alloy is increased from 30 μm to 51.13 μm, such that 21.13 μm is etched. Hence, the molybdenum (Mo)-tantalum (Ta) alloy was etched less than molybdenum (Mo) by about 50%, and it is observable that when a thickness of deposition is considered, the molybdenum (Mo)-tantalum (Ta) alloy was etched less than molybdenum (Mo) by about 25%.

That is, even in an example in which the molybdenum (Mo)-tantalum (Ta) alloy is inevitably exposed externally under the etching environment of the sacrificial air cavity layer pattern, reliability is secured due to robust characteristics for xenon fluoride (XeF₂).

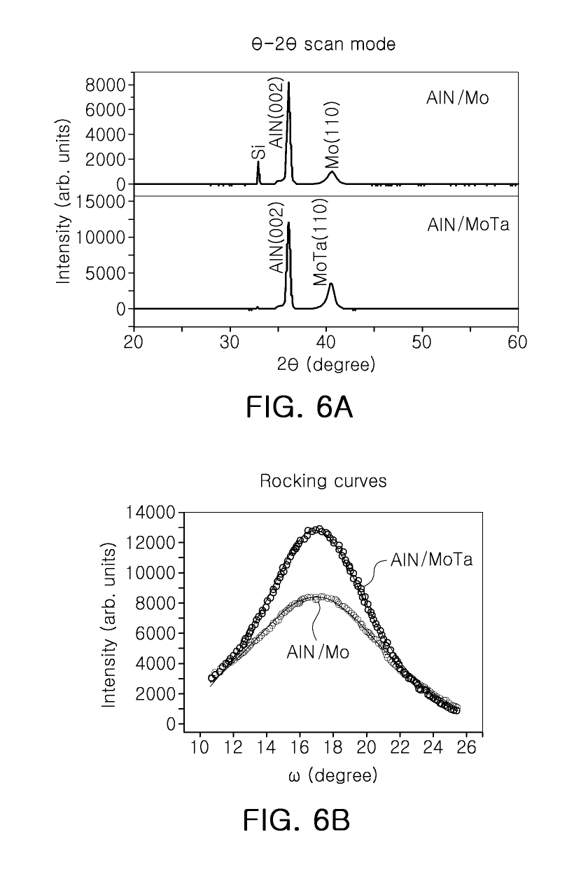

FIGS. 6A and 6B are diagrams illustrating crystal orientation of a piezoelectric layer at a molybdenum (Mo) alloy phase according to an example. As a material of the piezoelectric layer, aluminum nitride (AlN) was used in this example. However, alternative materials are potentially used, appropriately.

Referring to the example of FIG. 6A, it is observable that aluminum nitride (AlN) is grown in a forward direction or (002) direction on all of a molybdenum (Mo)-tantalum (Ta) alloy and pure molybdenum (Mo). However, referring to FIG. 6B, it is observable that a half-width of aluminum nitride (AlN) exhibits a smaller value under the molybdenum (Mo)-tantalum (Ta) alloy rather than pure molybdenum (Mo).

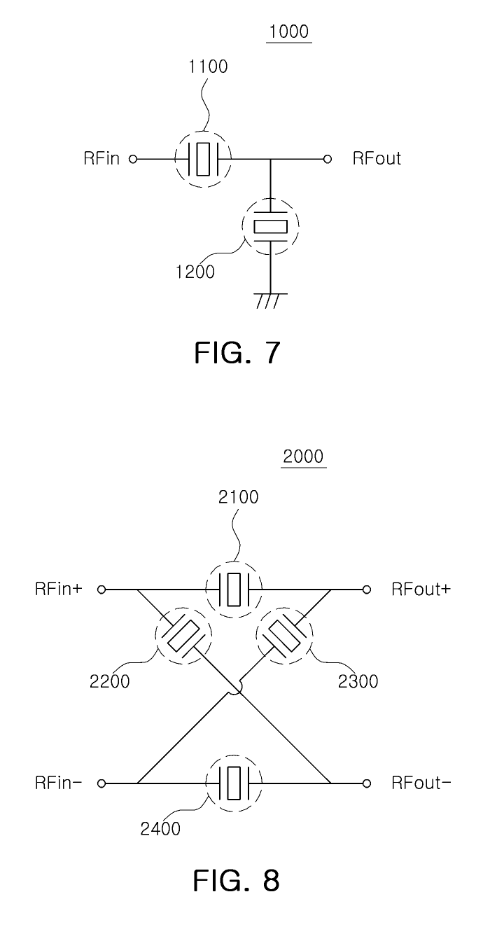

FIGS. 7 and 8 are schematic circuit diagrams of a filter according to examples.

Each of a plurality of bulk acoustic wave resonators employed in the filters of FIGS. 7 and 8 correspond to the bulk acoustic wave resonator illustrated in FIG. 1.

Referring to the example of FIG. 7, a filter 1000 according to an example is formed using a ladder type filter structure. Specifically, the filter 1000 includes a plurality of bulk acoustic wave resonators 1100 and 1200.

A first bulk acoustic wave resonator 1100 is connected between a signal input terminal to which an input signal RFin is input and a signal output terminal from which an output signal RFout is output in series. Furthermore, a second bulk acoustic wave resonator 1200 is connected between the signal output terminal and a ground.

Referring to FIG. 8, a filter 2000 according to an example is formed in a filter structure of a lattice type. Specifically, the filter 200 includes a plurality of bulk acoustic wave resonators 2100, 2200, 2300, and 2400 in order to filter balanced input signals RFin+ and RFin- and output balanced output signals RFout+ and RFout−.

As set forth above, according to the examples, the bulk acoustic wave resonator may secure reliability by preventing oxidation of the electrodes.

In addition, robust characteristics are secured from the etching material used in a process of manufacturing the bulk acoustic wave resonator.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation,

Expressions such as “first conductivity type” and “second conductivity type” as used herein may refer to opposite conductivity types such as N and P conductivity types, and examples described herein using such expressions encompass complementary examples as well. For example, an example in which a first conductivity type is N and a second conductivity type is P encompasses an example in which the first conductivity type is P and the second conductivity type is N.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave resonator comprising:
a substrate;
a first electrode and a second electrode formed on the substrate; and
a piezoelectric layer formed between the first electrode and the second electrode,
wherein at least one of the first electrode and the second electrode is formed of an alloy comprising molybdenum (Mo).

2. The bulk acoustic wave resonator of claim 1, wherein the alloy is a molybdenum (Mo)-tantalum (Ta) alloy manufactured by adding tantalum (Ta) to molybdenum (Mo).

3. The bulk acoustic wave resonator of claim 2, wherein a content of tantalum (Ta) in the alloy is 0.1 to 50 atm %.

4. The bulk acoustic wave resonator of claim 2, wherein a content of tantalum (Ta) in the alloy is 0.1 to 30 atm %.

5. The bulk acoustic wave resonator of claim 1, further comprising an air cavity formed between the substrate and the first electrode,
wherein a sacrificial air cavity layer pattern for forming the air cavity is etched using xenon fluoride.

6. The bulk acoustic wave resonator of claim 5, wherein the sacrificial air cavity layer pattern is etched after at least one of the first electrode and the second electrode is formed.

7. A filter comprising:
bulk acoustic wave resonators,
wherein each of the bulk acoustic wave resonators comprises
a substrate,
a first electrode and a second electrode formed on the substrate, and
a piezoelectric layer formed between the first electrode and the second electrode, wherein
at least one of the first electrode and the second electrode is formed of an alloy including molybdenum.

8. The filter of claim 7, wherein the alloy is a molybdenum (Mo)-tantalum (Ta) alloy manufactured by adding tantalum (Ta) to molybdenum (Mo).

9. The filter of claim 8, wherein a content of tantalum (Ta) in the alloy is 0.1 to 50 atm %.

10. The filter of claim 8, wherein a content of tantalum (Ta) in the alloy is 0.1 to 30 atm %.

11. The filter of claim 7, wherein each of the bulk acoustic wave resonators further comprises an air cavity formed between the substrate and the first electrode,
wherein a sacrificial air cavity layer pattern for forming the air cavity is etched using xenon fluoride.

12. The filter of claim 11, wherein the sacrificial air cavity layer pattern is etched after at least one of the first electrode and the second electrode is formed.

13. The filter of claim 7, wherein the bulk acoustic wave resonators are formed in a ladder type or a lattice type.

14. A bulk acoustic wave resonator comprising:
a first electrode and a second electrode formed on a substrate;
a piezoelectric layer formed between the first electrode and the second electrode; and
an air cavity formed between the substrate and the first electrode.

15. The bulk acoustic wave resonator of claim 14, wherein a sacrificial air cavity layer pattern for forming the air cavity is etched using xenon fluoride.

16. The bulk acoustic wave resonator of claim 14, wherein at least one of the first electrode and the second electrode is formed of an alloy including molybdenum.

17. The bulk acoustic wave resonator of claim 16, wherein the alloy is a molybdenum (Mo)-tantalum (Ta) alloy manufactured by adding tantalum (Ta) to molybdenum (Mo).
